(19) United States
(12) Patent Application Publication
(10) Pub. No.: US 2021/0358720 A1
(43) Pub. Date: Nov. 18, 2021

(54) SUBSTRATE TREATING APPARATUS

(71) Applicant: SEMES CO., LTD., Chungcheongnam-do (KR)

(72) Inventors: HANGLIM LEE, Cheonan-si (KR); MINYOUNG KIM, Hwaseong-si (KR); JIHOON PARK, Seoul (KR)

(21) Appl. No.: 17/315,322

(22) Filed: May 9, 2021

(30) Foreign Application Priority Data
May 12, 2020 (KR) 10-2020-0056692

(51) Int. Cl. H01J 37/32; H01L 21/67; H01L 21/687; B08B 7/00; G03F 7/42

(52) U.S. Cl. CPC H01J 37/32449; H01L 21/67034; H01L 21/68764; H01J 2237/335; H01J 37/32825; B08B 7/0035; G03F 7/427; H01J 37/32568

(57) ABSTRACT

An embodiment of the inventive concept provides a substrate treating apparatus. The substrate treating apparatus includes a lower electrode having an upper surface, on which a substrate is positioned, and a plasma generating device provided at an upper portion of the lower electrode, having an upper electrode, and having independent discharge spaces divided by a plurality of partition walls, and a controller that performs a control to independently supply a reaction gas into the independent discharge spaces, respectively.

### CROSS-REFERENCE TO RELATED APPLICATIONS

A claim for priority under 35 U.S.C. § 119 is made to Korean Patent Application No. 10-2020-0056692 filed on May 12, 2020, in the Korean Intellectual Property Office, the entire contents of which are hereby incorporated by reference.

### BACKGROUND

Embodiments of the inventive concept described herein relate to a substrate treating apparatus.

Plasma used industrially may be classified into low-temperature plasma and thermal plasma, and the low-temperature plasma has been most widely used in a semiconductor manufacturing process, and the thermal plasma has been applied to cutting of metals.

Atmospheric plasma means a technology for generating low-temperature plasma while maintaining the pressure of a gas at 100 Torr to the atmospheric pressure (760 Torr. Because an atmospheric plasma system does not require vacuuming equipment of high price, it is economical and has no pumping configuration and its process may be performed in an inline form, and thus a plasma system that may maximize productivity may be developed. Application fields that adopt the atmospheric plasma system may include a high-speed etching/coating technology, semiconductor packaging, displays, modification and coating of surfaces of materials, generation of nano-powder, removal of harmful gases, and generation of oxidized gases.

A linear type plasma generating device 1 for generating the atmospheric plasma may have one gas supply line 2, and may adopt a constant flow rate and a specific mixture ratio, and treats plasma while a to-be-treated object 3 is fed in a direction that is perpendicular to the lengthwise direction of the plasma generating device 1 (see FIG. 1).

Accordingly, because a space that corresponds to at least two times of the area of the to-be-treated object is necessary to move the to-be-treated object 3, an essential space becomes wider when the plasma treating device is constituted, and because an unnecessary portion (the outside of a circle that devices from the length of the plasma generating device) has to be treated when the to-be-treated object (wafer) is not rectangular but circular, a portion of a lower feeding device may be corroded.

### PRIOR TECHNICAL DOCUMENTS

### Patent Documents

Korean Patent Application Publication No. 10-2015-0101738

### SUMMARY

Embodiments of the inventive concept provide a substrate treating apparatus that may perform uniform plasma treatments on a circular to-be-treated object.

The technical objectives of the inventive concept are not limited to the above-mentioned ones, and the other unmentioned technical objects will become apparent to those skilled in the art from the following description.

According to an embodiment, a substrate treating apparatus includes a lower electrode having an upper surface, on which a substrate is positioned, a plasma generating device provided at an upper portion of the lower electrode, having an upper electrode, and having independent discharge spaces partitioned by a plurality of partition walls, and a controller that performs a control to independently supply a reaction gas into the independent discharge spaces, respectively.

Further, the plasma generating device may include a reactor body having a hollow bar shape and provided with the discharge spaces in an interior thereof, and an ejection hole provided on a bottom surface of the reactor body linearly along a lengthwise direction thereof, and which ejects plasma generated in the independent discharge spaces to the substrate positioned on the lowert electrode.

Furthermore, a length of the ejection hole may be equal to or larger than a diameter of the substrate.

Furthermore, the upper electrode may be configured to pass through the independent discharge spaces and an outer side of the upper electrode is surrounded by an insulator.

Furthermore, the lower electrode may be configured to be rotatable, and the partition walls may be nonconductors.

Furthermore, a cross-section of the upper electrode may be circular and a cross-section of the insulator may be annular.

Furthermore, cross-sectional shapes of the discharge spaces may be annular shapes that surround the upper electrode.

Furthermore, the reactor body may include supply ports, through which the reaction gas is introduced into the discharge spaces, respectively, gas supply lines may be connected to the supply ports, respectively, and the controller may control flow rates and mixing ratios of the reaction gas through control of valves on the gas supply lines.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view illustrating a general atmospheric plasma treating device;

FIG. 2 is a view illustrating a substrate treating apparatus according to an embodiment of the inventive concept;

FIG. 3 is a perspective view illustrating a substrate support unit and a plasma generating device of FIG. 2;

FIG. 4 is a cross-sectional view illustrating a plasma generating device;

FIG. 5 is a sectional view taken along line A-A of FIG. 4; and

FIG. 6 is a cross-sectional perspective view illustrating a main part of a plasma generating device.

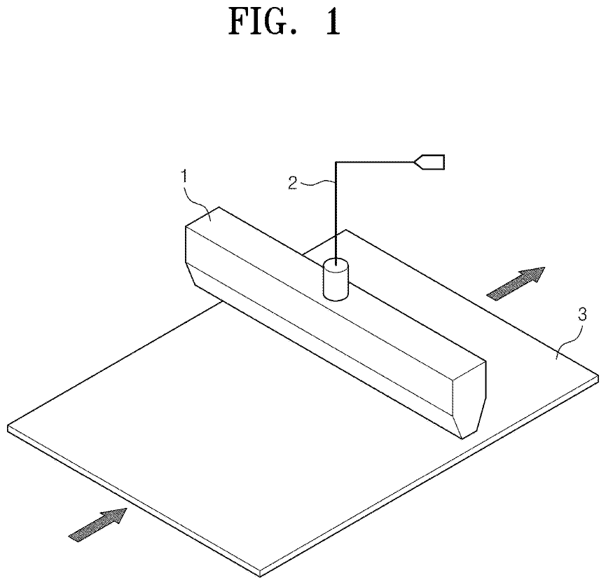

### DETAILED DESCRIPTION

The above and other advantages and features of the inventive concept, and methods of the inventive concept for achieving them will become apparent from the following description of the following embodiments which are given in conjunction with the accompanying drawings and will be described below in detail. However, the inventive concept is not limited to the embodiments, which will be disclosed hereinafter, and the inventive concept is defined only by the scope of the claims. Although not defined, all the terms (including technical or scientific terms) used herein may have the same meanings that are generally accepted by the common technologies in the field to which the present invention pertains. A general description of the known configurations may be omitted not to make the essence of the inventive concept obscure. In the drawings of the inventive concept, the same reference numerals are used to denote the same or similar configurations if possible. For easy understanding of the inventive concept, some configurations may be rather exaggerated or downscaled in the drawings.

The terminologies used herein are provided only to describe specific embodiments, and are not intended to limit the inventive concept. The terms of a singular form may include plural forms unless otherwise specified. The terms “including” and “having” are used to designate that the features, the numbers, the steps, the operations, the elements, the parts, or combination thereof described in the specification are present, and may be understood that one or more other features, numbers, step, operations, elements, parts, or combinations thereof may be added.

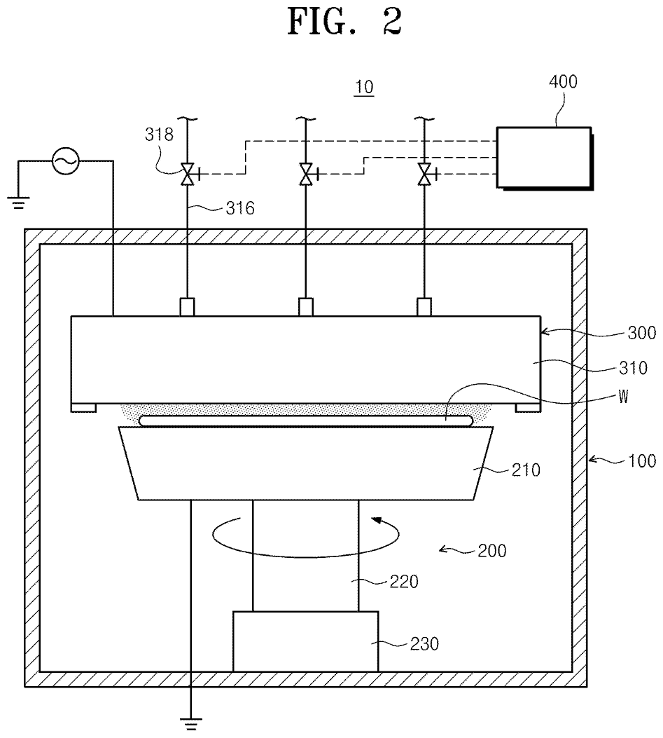

Hereinafter, a substrate treating apparatus of the inventive concept will be described with reference to FIGS. 2 to 6.

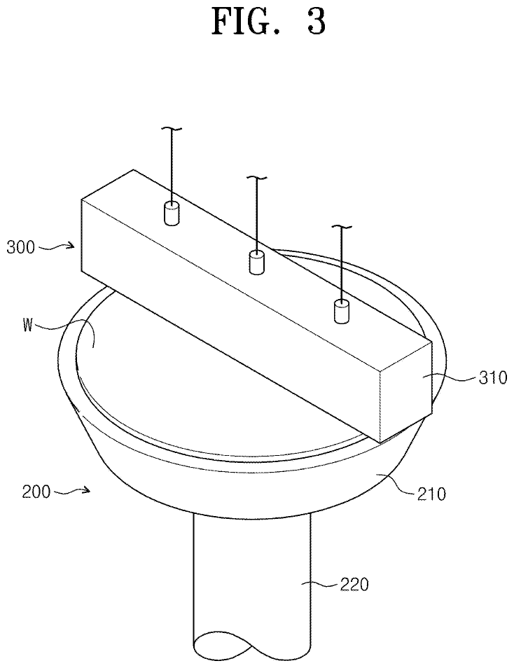

FIG. 2 is a view illustrating a substrate treating apparatus according to an embodiment of the inventive concept. FIG. 3 is a perspective view illustrating a substrate support unit and a plasma generating device of FIG. 2.

Referring to FIGS. 2 and 3, a substrate treating apparatus 10 is an apparatus that may perform a series of plasma surface treatments on a substrate for a semiconductor device by using atmospheric plasma.

For example, the substrate treating apparatus 10 according to the inventive concept may perform a cleaning process of removing organic materials (impurities) that reside on a surface of the substrate W, an ashing process of stripping a photoresist pattern on the surface of the substrate for passivation, and the like.

According to the present embodiment, the substrate treating apparatus 10 may include a process chamber 100 in an atmospheric state. The process chamber 100 has a housing or a wall, and a substrate support unit 200, on which the substrate W is positioned, is situated in the interior of the process chamber 100.

The substrate support unit 200 may support the substrate W during the process, and may be rotated by a driver 230, which will be described below, during the process. As an example, the substrate support unit 200 may have a circular upper surface, and may be a spin chuck having a spin head 210 used as a lower electrode. The substrate W may be fixed onto the spin head 210 by an electrostatic fore or may be fixed by a vacuum force. As another method, the substrate W may be fixed by chucking pins provided on the spin head 210.

A support shaft 220 supporting the spin head 210 is connected to a lower portion of the spin head 210, and the support shaft 220 is rotated by the driver 230 connected to a lower end thereof. The driver 230 may be a motor or the like. As the support shaft 220 is rotated, the spin head 210 and the substrate W are rotated. Meanwhile, the spin head 210 is grounded. That is, the spin head 210 is used as a lower electrode. The spin head 210 itself may be the lower electrode, or the lower electrode may be buried in the interior of the spin head 210.

A plasma generating device 300 is provided in the process chamber 100. The plasma generating device 300 is installed at an upper portion of the process chamber 100 to correspond to the spin head 210, and generates and ejects plasma gas that is necessary for treatment of the surface of the substrate.

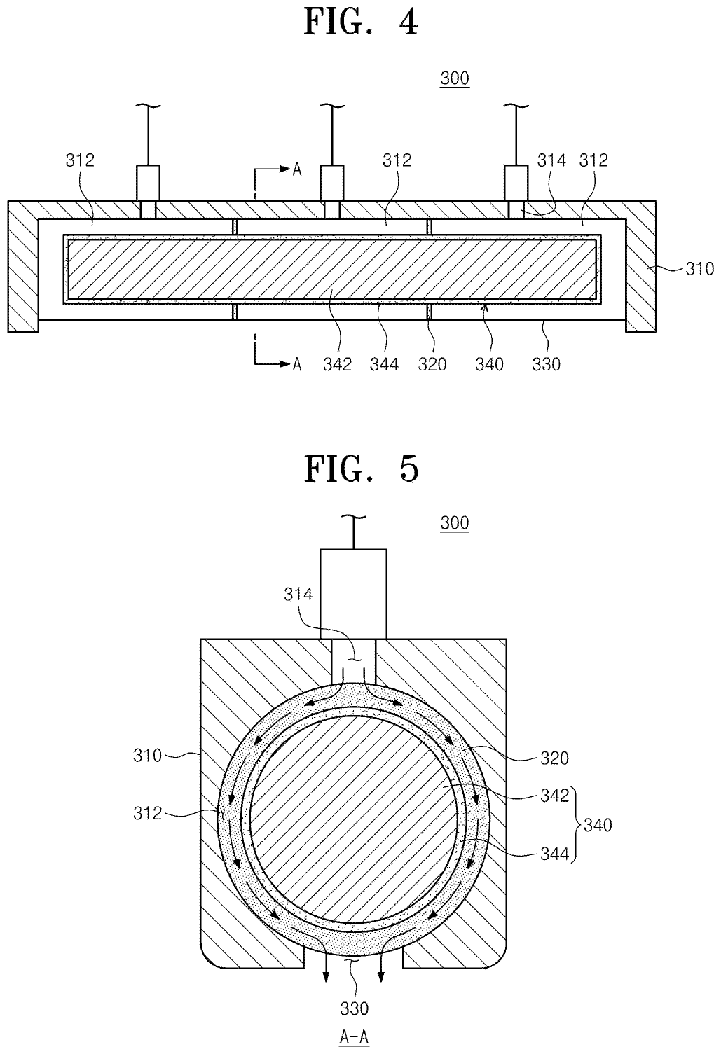

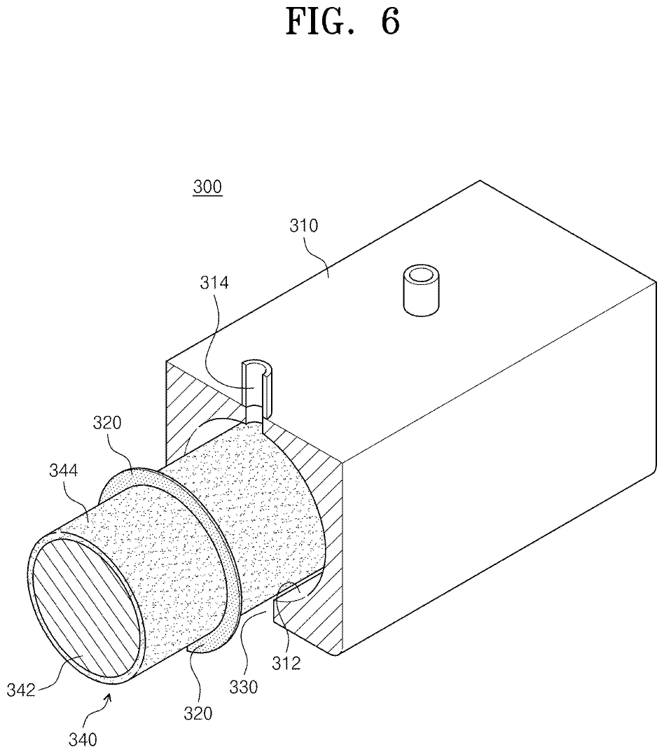

FIG. 4 is a cross-sectional view illustrating a plasma generating device. FIG. 5 is a sectional view taken along line A-A of FIG. 4. FIG. 6 is a cross-sectional perspective view illustrating a main part of a plasma generating device.

Referring to FIGS. 3 to 6, the plasma generating device 300 may include a reactor body 310 having a length (that is preferably larger than the diameter of the substrate) that corresponds to the diameter of the substrate.

The reactor body 310 may be arranged at an upper portion of the spin head 210 in parallel to the substrate W. For example, the reactor body 310 may have a bar shape that extends long in a hexagonal shape. The reactor body 310 has an empty space in the interior thereof, and a lower portion of the reactor body 310 is opened. The empty space in the interior of the reactor body 310 may have independent discharge spaces 312. The discharge spaces 312 may be partitioned by a plurality of partition walls 320. Although it is illustrated in the present embodiment that the reactor body 310 has three independent discharge spaces 312 divided by two partition walls 320, the inventive concept is not limited thereto and, preferably, three or more partition walls 320 may be provided. The reactor body 310 may be grounded.

Supply ports 314 for supplying a reaction gas to the discharge spaces 312 are installed at an upper end of the reactor body 310. As in FIG. 2, gas supply lines 316 connected to a gas supply source are connected to the supply ports 314, respectively.

The reactor body 310 has an ejection hole 330 on a bottom surface thereof. The ejection hole 330 may be formed linearly on the bottom surface of the reactor body 310 along a lengthwise direction of the reactor body 310. The ejection hole 330 is connected to the discharge spaces 312. The plasma generated in the independent discharge spaces 312 may be ejected to the substrate positioned on the spin head 210 through the ejection hole 330. It is preferable that the length of the ejection hole 330 is larger than the diameter of the substrate W.

Meanwhile, it is preferable that the reactor body 310 of the plasma generating device 300 is arranged such that the lengthwise center of the reactor body 300 is aligned with the center of the substrate treatment surface (the center of rotation of the substrate) according to a process condition.

The plasma generating device 300 has an upper electrode 340. The upper electrode 340 is configured to pass through the independent discharge spaces 312. The upper electrode 340 may include an electrode 342 and an insulator 344 that surrounds the electrode 342. As in FIGS. 5 and 6, the cross-section of the electrode 342 may be circular, and the cross-section of the insulator 344 for surrounding the electrode 342 may be annular. However, the cross-sections of the electrode 342 and the insulator 344 may have various shapes that are not limited thereto.

Although not illustrated, the electrode 342 may be provided with a passage, through which a refrigerant that suppresses emission of heat due to generation of the plasma passes.

For example, in order to minimize generation of heat due to discharge of electric charges, the electrode 342 may be formed of, for example, copper (Cu) or an alloy including copper, the electric resistance of which is low and the thermal conductivity of which is high. In addition, the insulator 344 may be formed of quartz (Si), alumina, a composite including alumina, or the like, which suppresses generation of heat due to discharge of electric charges and has a durability against plasma, and preferably, may be formed of aluminum nitride (AlN) that has an excellent thermal conductivity.

Although not illustrated, a high voltage may be applied to the electrode 342, and the lower electrode may be grounded to stably generate plasma.

Referring to FIG. 2 again, the substrate treating apparatus 10 may include a controller 400 for performing a control to independently supplying the reaction gas to the independent discharge spaces 312, respectively. The controller 400 may control the flow rates and the mixing ratios of the reaction gas through control of valves 318 on the gas supply lines 316 connected to the supply ports 314, respectively. Although not illustrated, at least two supply lines (gas MFCs) may be connected to the supply ports, respectively.

For example, the controller 400 may improve the plasma treatment uniformity of the entire substrate by controlling such that the flow rate of the reaction gas supplied to the discharge space corresponding to the central area of the substrate is smaller than the flow rate of the reaction gas supplied to the discharge space corresponding to a peripheral area of the substrate.

The substrate treating apparatus 10 having the above configuration may improve the treatment uniformity when the plasma treatment is performed while the substrate is rotated, by applying the flow rates and the mixing ratios of the gas introduced into the linear plasma generating device differently to the discharge spaces.

In particular, because the substrate treating apparatus 10 may concentrate the plasma treatment area only in the substrate with the rotating structure of the lower electrode when a circular substrate is treated, the devices provided under the substrate may be prevented from being damaged by plasma, and because an additional space for feeding the lower electrode is unnecessary, the size of the plasma treating device may be reduced.

According to the embodiment of the inventive concept, the treatment uniformity that may be generated when the plasma treatment is performed while the substrate is rotated may be improved, by applying the flow rates and the mixing ratios of the gas introduced into the linear plasma generating device differently to the discharge spaces.

The effects of the inventive concept are not limited to the above-mentioned effects, and the unmentioned effects can be clearly understood by those skilled in the art to which the inventive concept pertains from the specification and the accompanying drawings.

The above detailed description exemplifies the inventive concept. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to restrict the inventive concept in the disclosed embodiment state. Furthermore, it should be construed that the attached claims include other embodiments.

What is claimed is:

1. A substrate treating apparatus comprising:
a lower electrode having an upper surface, on which a substrate is positioned;
a plasma generating device provided at an upper portion of the lower electrode, having an upper electrode, and having independent discharge spaces partitioned by a plurality of partition walls; and
a controller configured to perform a control to independently supply a reaction gas into the independent discharge spaces, respectively.

2. The substrate treating apparatus of claim 1, wherein the plasma generating device includes:
a reactor body having a hollow bar shape and provided with the discharge spaces in an interior thereof; and
an ejection hole provided on a bottom surface of the reactor body linearly along a lengthwise direction thereof, and configured to eject plasma generated in the independent discharge spaces to the substrate positioned on the lower electrode.

3. The substrate treating apparatus of claim 2, wherein a length of the ejection hole is equal to or larger than a diameter of the substrate.

4. The substrate treating apparatus of claim 2, wherein the upper electrode is configured to pass through the independent discharge spaces and an outer side of the upper electrode is surrounded by an insulator.

5. The substrate treating apparatus of claim 2, wherein the lower electrode is configured to be rotatable, and the partition walls are nonconductors.

6. The substrate treating apparatus of claim 2, wherein a cross-section of the upper electrode is circular and a cross-section of an insulator is annular.

7. The substrate treating apparatus of claim 2, wherein cross-sectional shapes of the discharge spaces are annular shapes that surround the upper electrode.

8. The substrate treating apparatus of claim 2, wherein the reactor body includes supply ports, through which the reaction gas is introduced into the discharge spaces, respectively,
wherein gas supply lines are connected to the supply ports, respectively, and
wherein the controller controls flow rates and mixing ratios of the reaction gas through control of valves on the gas supply lines.

9. A substrate treating apparatus comprising:
a spin head having an upper surface, on which a substrate is positioned, and in which a lower electrode is arranged in an interior thereof;
a plasma generating device arranged on the spin head; and
a plurality of gas supply units configured to a supply reaction gas to the plasma generating device,
wherein the plasma generating device includes:
a reactor body having discharge spaces in an interior thereof;
an upper electrode arranged in the discharge spaces;
partition walls arranged between the reactor body and the upper electrode and configured to partition the discharge spaces, and
wherein the number of the gas supply units corresponds to the number of the plurality of discharge spaces.

10. The substrate treating apparatus of claim 9, further comprising:
a controller configured to control the gas supply units, and
wherein the controller performs a control to independently supply the reaction gas into the plurality of discharge spaces, respectively.

11. The substrate treating apparatus of claim 9, wherein the reactor body includes:
an upper wall;
a lower wall arranged on an opposite side of the upper wall; and
first to fourth side walls connecting the upper wall and the lower wall, and
wherein an ejection hole that is opened in a direction that faces the substrate positioned on the spin head is formed in the lower wall.

12. The substrate treating apparatus of claim 11, wherein each of the gas supply units includes:
a supply port formed on in the upper wall; and
a gas supply line connected to the supply port, and
wherein an inner diameter of the ejection hole is larger than an inner diameter of the supply port.

13. The substrate treating apparatus of claim 9, wherein the upper electrode includes:
an electrode; and
an insulator arranged on an outer peripheral surface of the electrode, and
wherein the partition walls are arranged between the insulator and the reactor body.

14. The substrate treating apparatus of claim 9, wherein the partition walls include a first partition wall and a second partition wall that are spaced apart from each other,
wherein the discharge spaces include:
a first discharge space formed between the first partition wall and the reactor body;
a second discharge space formed between the first partition wall and the second partition wall; and
a third discharge space formed between the second partition wall and the reactor body,
wherein the second discharge space faces a central area of the substrate positioned on the spin head, and
wherein the first discharge space and the third discharge space face a peripheral area of the substrate positioned on the spin head.

15. The substrate treating apparatus of claim 14, wherein each of the gas supply units includes:
a first gas supply line configured to supply the reaction gas to the first discharge space;
a second gas supply line configured to supply the reaction gas to the second discharge space; and
a third gas supply line configured to supply the reaction gas to the third discharge space,
wherein the substrate treating apparatus further comprises: a controller configured to control the gas supply units such that the reaction gas is independently supplied to the first to third discharge space, respectively, and
wherein the controller controls such that a flow rate of the reaction gas supplied to the second discharge space and flow rates of the reaction gas supplied to each of the first and third discharge spaces are different.

16. The substrate treating apparatus of claim 9, wherein the spin head is configured to be rotatable, and the partition walls are nonconductors.

17. The substrate treating apparatus of claim 13, wherein a cross-section of the electrode of the upper electrode is circular and a cross-section of the insulator of the upper electrode is annular.

18. The substrate treating apparatus of claim 17, wherein cross-sectional shapes of the discharge spaces are annular shapes that surround the upper electrode.

19. A substrate treating apparatus comprising:
a lower electrode having an upper surface, on which a substrate is positioned;
a plasma generating device arranged at an upper portion of the lower electrode;
gas supply units configured to supply a reaction gas to the plasma generating device; and
a controller configured to control the gas supply units,
wherein the plasma generating device includes:
a reactor body having discharge spaces in an interior thereof;
a first partition wall and a second partition walls configured to partition the discharge spaces to first to third independent discharge spaces; and
an upper electrode arranged in the discharge spaces and passing through the plurality of partition walls,
wherein the gas supply units include:
a first gas supply unit configured to supply the reaction gas to the first discharge space;
a second gas supply unit configured to supply the reaction gas to the second discharge space; and
a third gas supply unit configured to supply the reaction gas to the third discharge space, and
wherein the controller controls the first to third gas supply units such that the reaction gas is independently supplied to the first to third discharge spaces.

20. The substrate treating apparatus of claim 19, wherein the second discharge space faces a central area of the substrate positioned on the lower electrode, and
wherein the first discharge space and the third discharge space face a peripheral area of the substrate positioned on the lower electrode, and
wherein the controller controls such that a flow rate of the reaction gas supplied to the second discharge space and flow rates of the reaction gas supplied to the first and third discharge spaces are different.
